(19) United States
(12) Patent Application Publication
(10) Pub. No.: US 2005/0184317 A1
(43) Pub. Date: Aug. 25, 2005

(54) Semiconductor device

(76) Inventors: Tetsuo Hatakeyama, Yokohama-shi (JP); Takashi Shinohe, Yokosuka-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/024,419

(22) Filed: Dec. 30, 2004

(30) Foreign Application Priority Data
Feb. 19, 2004 (JP) 2004-042561

(51) Int. Cl. H01L 29/80

(52) U.S. Cl. 257/262

(57) ABSTRACT

A semiconductor device comprises a first-conductivity-type semiconductor substrate, a first-conductivity-type first semiconductor layer formed on the semiconductor substrate, a second semiconductor layer formed on the first semiconductor layer and has a first-conductivity-type impurity concentration higher than that of the first semiconductor layer, a second-conductivity-type first semiconductor region selectively formed on an upper surface of the first semiconductor layer at a boundary with the second semiconductor layer, a source electrode selectively formed on the second semiconductor layer and achieves ohmic contact with the second semiconductor layer and the first semiconductor region, a gate electrode selectively formed on the second semiconductor layer and achieves Schottky contact with the second semiconductor layer, and a drain electrode formed on a lower surface of the semiconductor substrate and achieves ohmic contact with the semiconductor substrate.

### CROSS-REFERENCE TO RELATED APPLICATIONS

This application is based upon and claims the benefit of priority from prior Japanese Patent Application No. 2004-042561, filed Feb. 19, 2004, the entire contents of which are incorporated herein by reference.

### BACKGROUND OF THE INVENTION

1. Field of the Invention

The present invention relates to a semiconductor device, and more particularly to a switching device having a built-in anti-parallel diode which is used for motor driving.

2. Description of the Related Art

As a switching device used in a power control circuit, there are known devices such as an MOSFET using Si or an insulated gate bipolar transistor (IGBT) and others. These devices are used in a pulse width modulation (PWM) control inverter circuit shown in FIG. 1 which is a typical application of power semiconductor devices.

In the inverter circuit shown in FIG. 1, for example, diodes D1 to D4 each of which has an anode connected with an emitter of an IGBT formed by using an Si substrate and a cathode connected with a corrector of the IGBT (referred to as “anti-parallel connection” hereinafter) must be respectively arranged in switching devices TR1 to TR4 each of which comprises the IGBT. The diodes D1 to D4 serve to return a current flowing through an inductive load in the PWM control.

In the inverter circuit, if an IGBT or a gate turn-off thyristor (GTO) is used as the switching device, since an anti-parallel-connected built-in diode does not exist in the IGBT, a high-speed diode, e.g., a flywheel diode must be externally provided. Therefore, there occurs a problem of an increase in cost.

When an MOSFET is used as the switching device, since the anti-parallel-connected built-in diode exists in the MOSFET, a high-speed diode does not have to be externally provided. However, this built-in diode comprises a p-type diffusion layer and an n-type diffusion layer constituting a source of the MOSFET, and a built-in voltage at a PN junction constituted of these diffusion layers is relatively large. Therefore, there is a problem that the conduction loss becomes large and the switching speed at which minority carriers are stored in a conduction mode becomes slow.

In recent years, a power control semiconductor device using silicon carbide (SiC) which is a semiconductor material whose built-in potential is quite larger than that of silicon has come into practical use, and it has been experimentally proved that this semiconductor device has excellent characteristics, i.e., a higher breakdown voltage than that of a conventional device using silicon.

As the switching device using SiC, a device realized by short-circuiting a source of a junction field-effect transistor formed by using an SiC substrate (referred to as an “SiCJFET” hereinafter) and a drain of an MOSFET formed by using an Si substrate (referred to as an “SiMOSFET” hereinafter), which is a so-called cascode-connected compound device (referred to as an “SiC cascode device” hereinafter) has come into practical use (“Turn-off and short circuit behaviour of 4H SiC JFETs”, by B. Weis et al., Proceedings of 2001 IEEE Industry Applications Society 36th Annual Meeting-IAS'01, pp. 365-369).

FIG. 2 shows an equivalent circuit diagram of an SiC cascode device. Reference numeral 101 denotes a vertical SiCJFET; reference numeral 102, an SiMOSFET; and reference numeral 103, a built-in (intrinsic) diode of the SiMOSFET. FIG. 3 shows a structural cross-sectional view of the JFET 101 used in this cascode device. It seems that the MOSFET formed on an SiC substrate (referred to as an “SiCMOSFET” hereinafter) has a better trade-off between a breakdown voltage and a drift layer resistance than the SiMOSFET, but the SiCMOSFET is yet to come into practical use, since it has a large resistance at a channel portion below a gate electrode, resulting in high resistance of the device itself.

Meanwhile, a part between a gate and a drain of the SICJFET 101 shown in FIG. 3 constitutes a PN junction, and the SICJFET 101 likewise has a structure including a built-in diode like the SIMOSFET 102. A built-in voltage of this built-in diode is as large as 3V, the built-in diode 103 of the SIMOSFET 102 is turned on before this built-in diode is turned on, and the SICJFET 101 cannot serve as an anti-parallel-connected diode. Therefore, there is a problem that the switching speed of this SiC cascode device is limited by the speed of the built-in diode 103 of the SIMOSFET 102.

Therefore, realization of a switching device having a built-in high-speed anti-parallel-connected diode which is preferable to be used in an inverter circuit has been demanded.

### BRIEF SUMMARY OF THE INVENTION

According to a first aspect of the invention, there is provided a semiconductor device which comprises:
a semiconductor substrate including a first-conductivity-type impurity;
a first semiconductor layer formed on the semiconductor substrate including a first-conductivity-type impurity;
a second semiconductor layer formed on the first semiconductor layer and having a first-conductivity-type impurity concentration higher than that of the first semiconductor layer;
a first semiconductor region including a second-conductivity-type impurity, and selectively formed on an upper surface of the first semiconductor layer;
a source electrode selectively formed on the second semiconductor layer and achieves ohmic contact with the second semiconductor layer and the first semiconductor region;
a gate electrode selectively formed on the second semiconductor layer and achieves Schottky contact with the second semiconductor layer; and
a drain electrode formed on a lower surface of the semiconductor substrate and achieves ohmic contact with the semiconductor substrate.

According to a second aspect of the invention, there is provided a semiconductor device which comprises:
a junction field-effect transistor which has a first source electrode, a first drain electrode and a first gate electrode formed on a first semiconductor substrate, the first gate electrode achieving Schottky contact with the semiconductor substrate; and
a MIS field-effect transistor which has a second source electrode, a second drain electrode and a second gate electrode formed on a second semiconductor substrate, the second drain electrode being connected with the first source electrode.

According to a third aspect of the invention, there is provided a semiconductor device which comprises:
a semiconductor substrate including a first-conductivity-type impurity;
a first semiconductor layer including a first-conductivity-type impurity, and formed on the semiconductor substrate;
a second semiconductor layer formed on the first semiconductor layer and having a first-conductivity-type impurity concentration higher than that of the first semiconductor layer;
a first semiconductor region including a second-conductivity-type impurity, and selectively formed on an upper surface of the first semiconductor layer;
a source electrode selectively formed on the second semiconductor layer and achieves ohmic contact with the second semiconductor layer and the first semiconductor region;
a gate electrode selectively formed on the second semiconductor layer and achieves Schottky contact with the second semiconductor layer;
a plurality of second semiconductor regions each including a second-conductivity-type impurity, and selectively formed on the second semiconductor layer below the gate electrode; and
a drain electrode formed on a lower surface of the semiconductor substrate and achieves ohmic contact with the semiconductor substrate.

### BRIEF DESCRIPTION OF THE SEVERAL VIEWS OF THE DRAWING

FIG. 1 is a circuit diagram of a conventional inverter circuit;

FIG. 2 is a circuit diagram of a conventional SiC cascode device;

FIG. 3 is a cross-sectional view of a conventional JFET;

FIG. 4 is a partial circuit diagram of an inverter circuit constituted of an SiC cascode device comprising a JFET according to the present invention;

FIG. 5 is a cross-sectional view of a JFET according to a first embodiment of the present invention;

FIG. 6 is a plan view of the JFET according to the first embodiment;

FIG. 7 is another plan view of the JFET according to the first embodiment;

FIG. 8 is a view showing I-V characteristics of the JFET according to the first embodiment;

FIGS. 9 to 15 are cross-sectional views showing respective manufacturing steps of the JFET according to the first embodiment;

FIG. 16 is a cross-sectional view showing a JFET according to a second embodiment;

FIG. 17 is a cross-sectional view showing a JFET according to a third embodiment;

FIG. 18 is a cross-sectional view of a JFET according to a fourth embodiment; and

FIG. 19 is a cross-sectional view of a JFET according to a fifth embodiment.

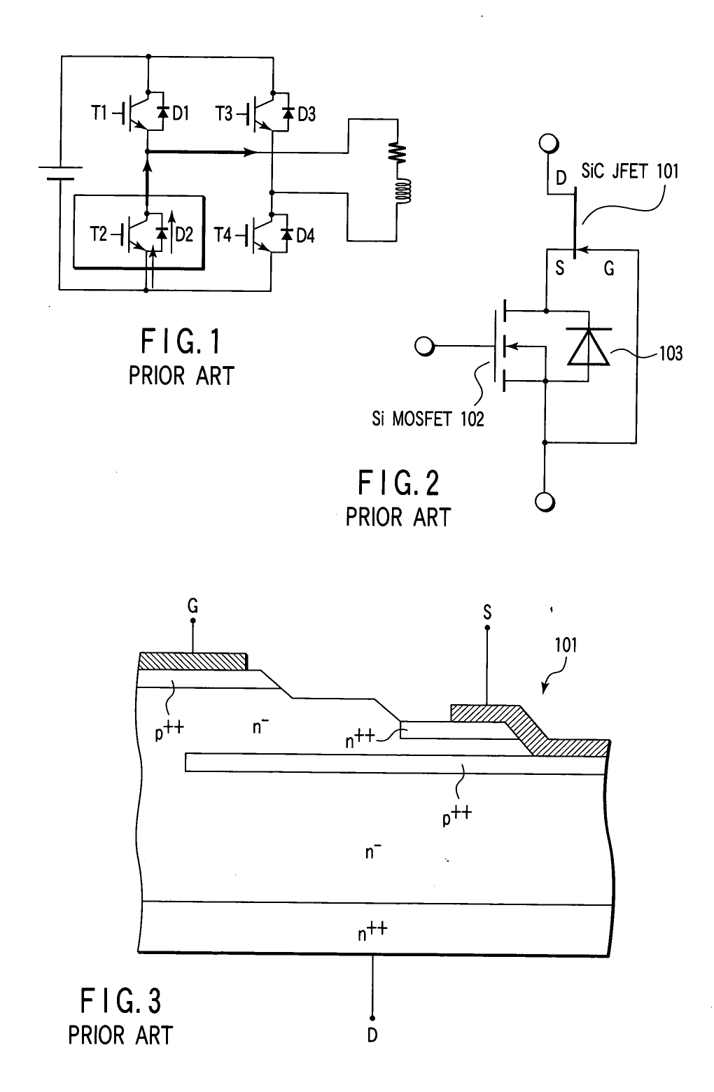

### DETAILED DESCRIPTION OF THE INVENTION

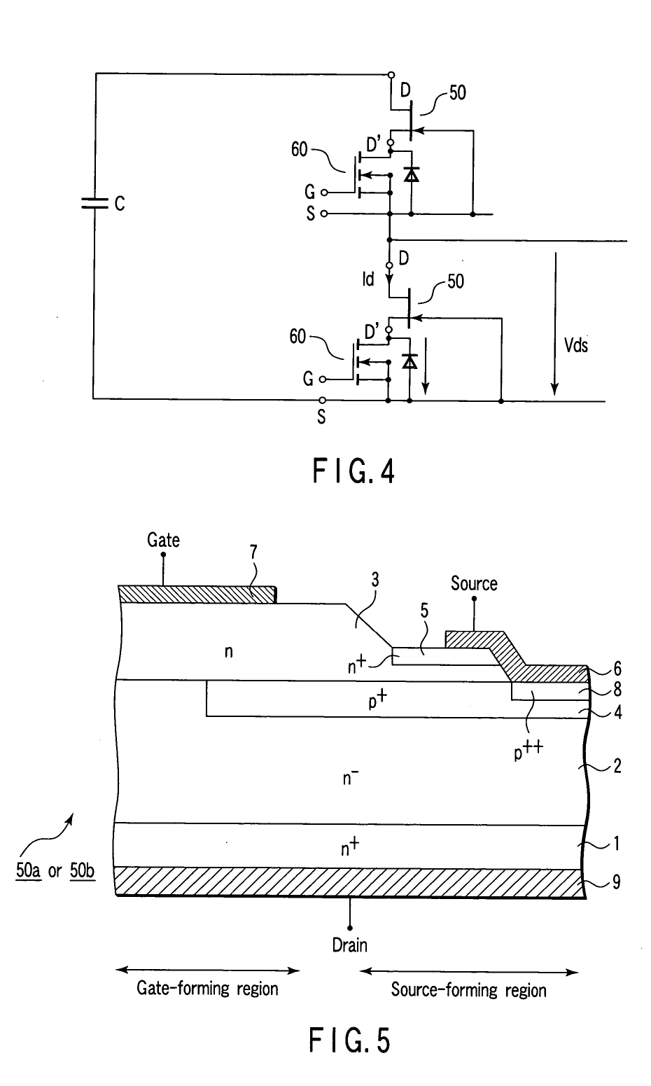

A JFET 50 in the embodiments according to the present invention described below has normally-on characteristics, and is connected in series with an SIMOSFET 60 as shown in FIG. 4 in order to constitute an SiC cascode device having normally-off characteristics. It appears from the outside that how this SiC cascode device operates is the same as a voltage-driven MOSFET device. In an inverter circuit using the SiC cascode device shown in FIG. 4, during the off cycle of a PWM control, a return current flows through a gate electrode of the JFET 50 rather than a built-in diode of the SIMOSFET 60. That is because a built-in Schottky diode of the JFET 50 has a smaller built-in voltage than the built-in diode of the MOSFET 60, and hence the built-in diode of the JFET 50 is turned on first. Since the built-in diode of the JFET 50 is the Schottky diode, no carrier is stored, and the built-in diode can immediately enter a non-conduction state upon termination of the off cycle operation of PWM, thereby greatly reducing switching losses. With such a configuration, both a reduction in cost realized by exploiting the built-in device of the switching device and an advantage of reducing switching losses can be achieved.

Embodiments according to the present invention will now be described hereinafter with reference to the accompanying drawings.

### First Embodiment

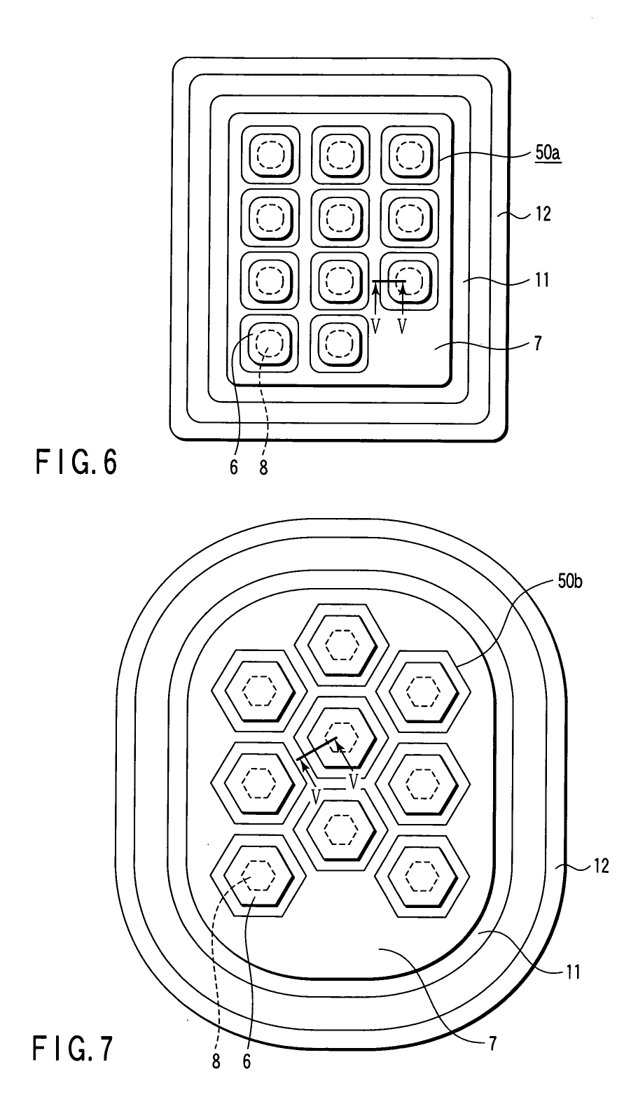

FIG. 5 shows a vertical section of one unit device of a JFET 50 according to the present invention used in an SiC cascode device. It is to be noted that a power semiconductor device adopts a configuration in which a plurality of unit devices are connected in parallel, and FIGS. 6 and 7 show plan views of an entire semiconductor device. FIG. 6 shows an example wherein unit device 50a are arrayed in a checker form, and FIG. 7 shows an example where unit devices 50b are arrayed in a staggered form. FIG. 5 is a cross-sectional view taken along the line V-V in FIG. 6 or FIG. 7. Further, in FIGS. 6 and 7, reference numeral 6 designates a source electrode; 7, a gate electrode (bonding pad), 11, an edge termination structure; and 12, an n+ channel stopper.

A cross-sectional structure of each unit device 50a (or 50b) will now be described with reference to FIG. 5. An n-type first semiconductor layer 2 with a high resistance (with a low impurity concentration) obtained by subjecting SiC to epitaxial growth is provided as an electric field relaxing layer on one surface of a highly-doped n-type SiC substrate 1. Although an impurity concentration and a thickness of the first semiconductor layer 2 are determined based on a designed breakdown voltage of the JFET 50, the impurity concentration is 1×10¹⁶ cm⁻³ and a thickness is 14 μm in case of a breakdown voltage of 1800V, for example. The impurity concentration of the SiC substrate 1 is, e.g., 1×10¹⁹ cm⁻³. As an n-type impurity of the SiC substrate 1, there is used nitrogen, phosphor, arsenic or the like, for example.

An n-type second semiconductor layer 3 having a higher impurity concentration than that of the first semiconductor layer 2 is formed on the first semiconductor layer 2 by subjecting SiC to epitaxial growth. An impurity concentration of this second semiconductor layer 3 is 5×10¹⁶ cm⁻³ and a thickness of the same is 3 μm, for example. Such steps as shown in FIG. 5 are provided on the surface of the second semiconductor layer 3, and a higher step is determined as a gate region whilst a lower step is determined as a source region. However, the shape is not restricted to one shown in FIG. 5.

Further, a first semiconductor area 4 as a p-type semiconductor layer is provided on the first semiconductor layer 2 in the vicinity of a boundary between the first semiconductor layer 2 and the second semiconductor layer 3. An impurity concentration of this first semiconductor area 4 is, e.g., 1×10¹⁸ cm⁻³. As a p-type impurity, aluminium, boron or the like is used, for example. Furthermore, a p⁺⁺ type semiconductor area 8 with a higher impurity concentration is selectively provided on an upper surface of the first semiconductor area 4.

Moreover, a second semiconductor area 5 including a highly-doped n-type impurity is selectively provided on a source forming region surface in the second semiconductor layer 3. An impurity concentration of this area is, e.g., 1×10²⁰ cm⁻³. The source electrode 6 is provided on the surface of the second semiconductor area 5, and short-circuited with the embedded first semiconductor area 4 through the p⁺⁺ type semiconductor area 8.

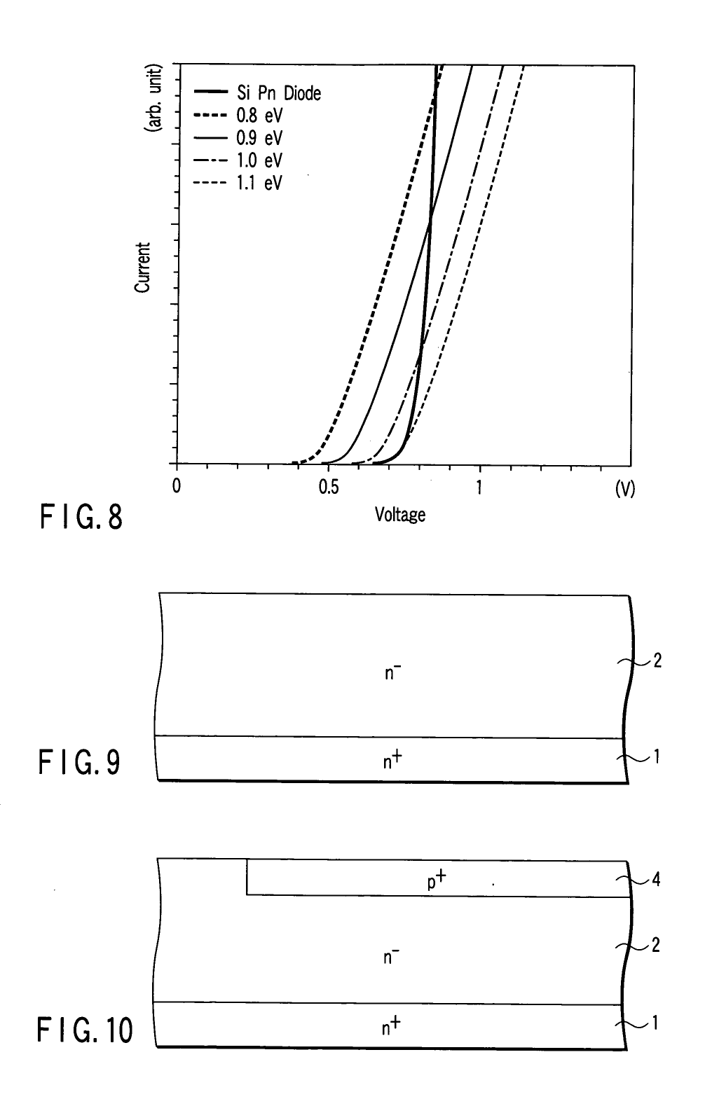

Additionally, the gate electrode 7 which forms a Schottky junction with the second semiconductor layer 3 is provided on a gate forming region surface in the semiconductor layer 3, and a drain electrode 9 is formed on the other surface of the SiC substrate. It is appropriate to set a height of an energy barrier (referred to as a “Schottky barrier” hereinafter) in the Schottky junction between the second semiconductor layer 3 and the gate electrode 7 to be not more than 1.1 eV, e.g., 0.9 eV. The reason will be described in detail hereinafter with reference to FIG. 8.

FIG. 8 shows a comparison of I-V characteristics between an SiPN diode and an SiC Schottky barrier diode (corresponding to the JFET 50 in this embodiment and referred to as an “SiCSBD” hereinafter). Numeric values (parameters) of 0.8 to 1.1 shown in the drawing indicate each Schottky barrier (unit: eV) of the SiCSBD.

As shown in FIG. 8, when an absolute value of a height of the SiC Schottky is smaller than 1.1 eV, a voltage with which a current of the SiCSBD starts to flow is lower than a voltage of the SIPN diode. That is because a magnitude of a band gap of Si is approximately 1.1 eV, and hence an absolute value of a height of the Schottky barrier of SiC is smaller than the band gap of Si. Therefore, the built-in diode of the SiMOSFET 60 in this embodiment is not turned on, but the Schottky diode of the JFET 50 is turned on. As a result, a switching speed of the SiC cascode device can be increased.

Operation of the JFET 50 according to the present invention will now be described. When a negative bias voltage is applied to the gate electrode 7, a depletion layer expands from the gate electrode 7. On the other hand, the pn junction is formed between the embedded first semiconductor area 4 and the second semiconductor layer 3, and a depletion layer expands from the first semiconductor area 4 to some extent by a built-in potential of this pn junction. The depletion layer expanding from the first semiconductor layer 4 is coupled with the depletion layer expanding from the gate electrode 7, thereby blocking a conduction path between the source electrode 6 and the first semiconductor layer 2.

On the other hand, when a positive bias voltage is applied to the gate electrode 7, electrons can get over the Schottky barrier between the gate electrode 7 and the second semiconductor layer 3. Then, a current flows into the drain electrode 9 from the gate electrode 7 through the first semiconductor layer 2 and the second semiconductor layer 3.

Manufacturing steps according to this embodiment will now be described.

First, as shown in FIG. 9, the n-type first semiconductor region 2 having an impurity concentration of approximately 1×10¹⁶ cm⁻³ is epitaxially grown for approximately 10 μm on the n⁺ type SiC substrate 1 having an impurity concentration of 1×10¹⁹ cm⁻³. After the growth, as shown in FIG. 10, a mask pattern is formed on the first semiconductor layer 2, and a dose of approximately 5×10¹³ cm⁻³ of aluminium (a p-type impurity) is selectively ion-implanted, thereby forming a p⁺ type area which serves as the first semiconductor region 4.

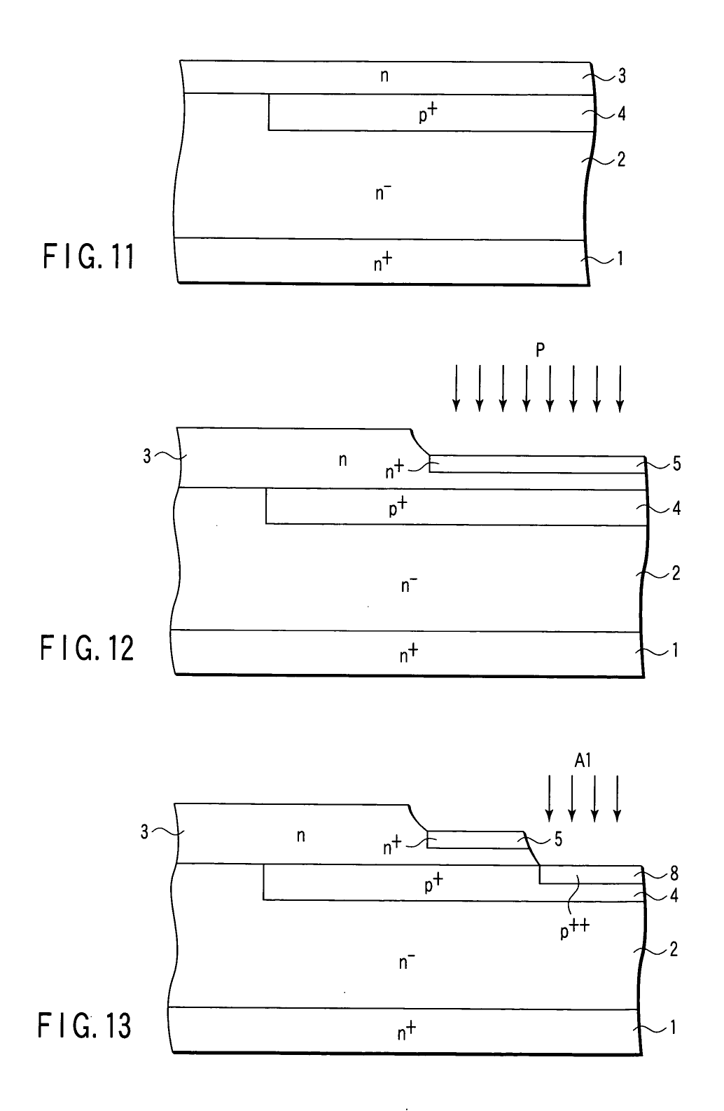

Then, as shown in FIG. 11, the n-type second semiconductor layer 3 containing an impurity whose concentration is approximately 5×10¹⁶ cm⁻³ is epitaxially grown on the first semiconductor layer 2 after ion implantation. After the epitaxial growth, a part of the second semiconductor layer 3 is removed by isotropic etching, as shown in FIG. 12, and an n-type impurity is ion-implanted to the part whose height is reduced by etching, thereby forming the n⁺ type second semiconductor region 5. A dose is, e.g., 5×10¹⁵ cm⁻³. An end portion of this second semiconductor region 5 (a central portion of the unit device in FIG. 6) is selectively removed by isotropic etching as shown in FIG. 13. Approximately 1×10¹⁶ cm⁻² of a p-type impurity is ion-implanted to the surface of the first semiconductor layer 2 exposed by this etching, thereby forming a p⁺⁺ region 8. This dose is selected so that the ion-implanted surface can be ohmic-connected with a material of the source electrode formed on this surface.

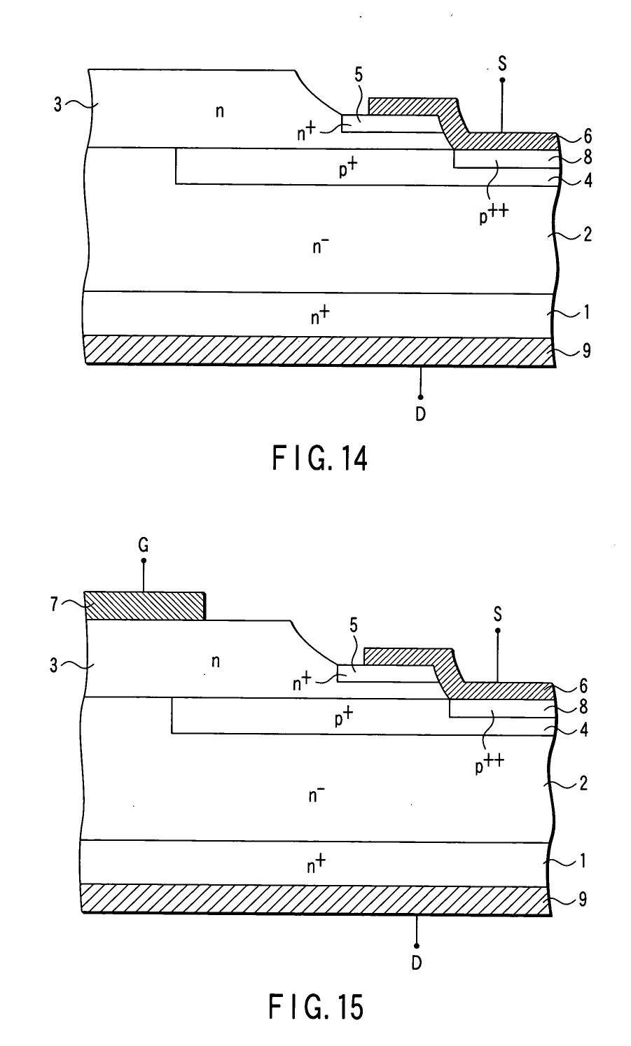

After ion implantation, as shown in FIG. 14, the SiC substrate 1 is annealed at approximately 1600° C., and the impurities ion-implanted in the above-described manufacturing steps are activated altogether. Thereafter, the source electrode 6 is formed by sputtering a metal such as Ti or W to the source region on the first semiconductor region 4 and the second semiconductor region 5. Alternatively, after sputtering, annealing may be performed at approximately 1000° C. in order to form silicide. Likewise, as shown in FIG. 15, the gate electrode 7 is formed by sputtering a metal such as Ti or W to the gate region on the second semiconductor layer 3. Further, likewise, after sputtering, annealing may be performed at approximately 1000° C. in order to form silicide.

### Second Embodiment

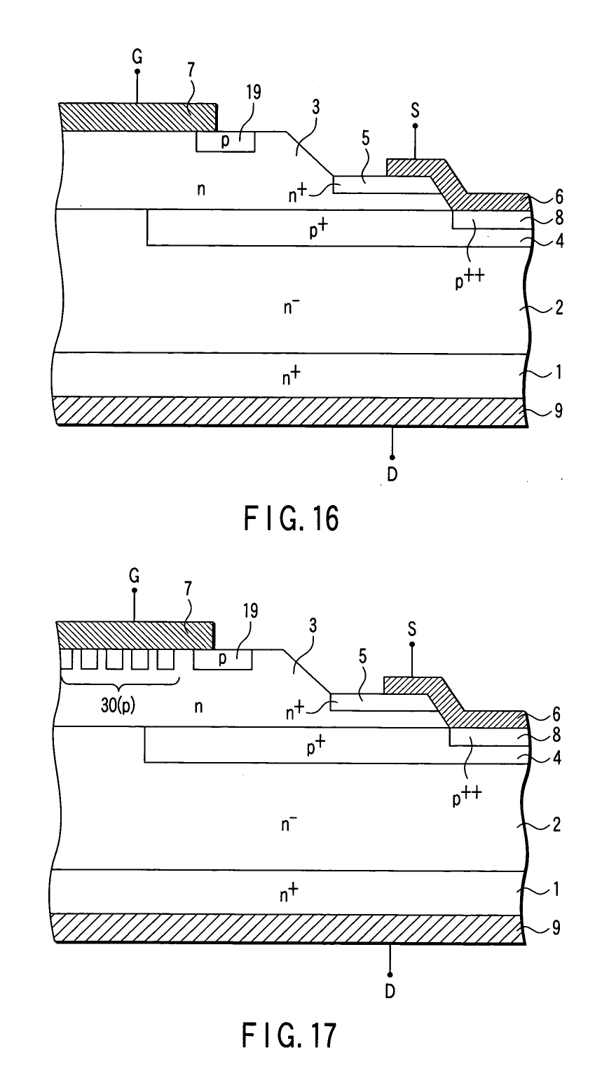

FIG. 16 shows a cross-sectional view of a unit device constituting a semiconductor device according to a second embodiment. In a JFET according to this embodiment, since an electric-field concentration tends to occur at an end portion of a gate electrode 17, a first p-type layer 19 is provided at the end portion of the gate electrode 17. It is sufficient to form the first p-type layer 19 at a surface part of a second semiconductor layer 13 which faces the end portion of the gate electrode 17. The first p-type layer 19 is formed by ion implantation of aluminium or boron, and its dose is 1×10¹³ to 5×10¹⁴ cm⁻³. Any other structure is the same as the first embodiment, thereby eliminating its explanation.

### Third Embodiment

FIG. 17 shows a cross-sectional view of a unit device which constitutes a semiconductor device according to a third embodiment. In the configuration of the JFET according to the first embodiment, in cases where a negative bias voltage is applied to the gate electrode 7, when a high voltage is applied to the drain electrode 9, a high electric field is generated at the Schottky barrier. Therefore, electrons tunnel through the Schottky barrier, and a leakage current flows between the gate electrode 7 and the drain electrode 9. Thus, in order to prevent a high electric field from being applied at the Schottky barrier, it is possible to adopt such a configuration as shown in FIG. 17 in which a plurality of second p-type layers 30 are provided under the Schottky barrier in such a manner that these layers come into contact with the barrier, thereby relaxing the electric field. The second p-type layer 30 is formed by ion implantation of aluminium or the like, and its dose is 1×10¹³ to 5×10¹⁴ cm⁻³. Any other structure is the same as the second embodiment, thereby eliminating its explanation.

### Fourth Embodiment

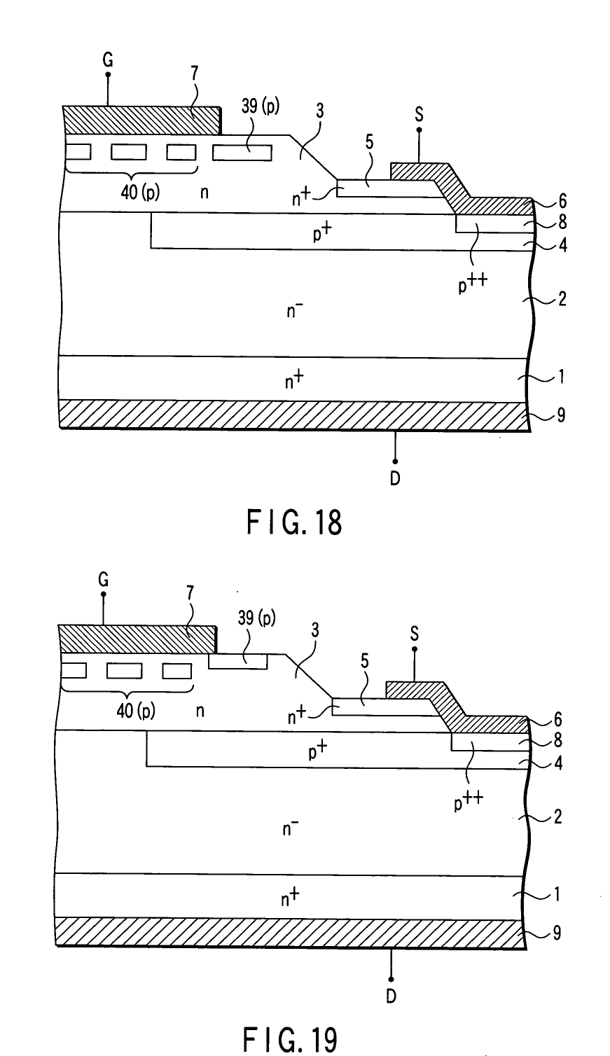

FIG. 18 shows a cross-sectional view of a unit device constituting a semiconductor device according to a fourth embodiment. A difference of this embodiment from the third embodiment lies in that third p-type layers 40 and a fourth p-type layer 39 are provided at portions apart from the Schottky barrier even though these portions are directly below the Schottky barrier. In case of the configuration shown in FIG. 17, when a positive bias voltage is applied, a current flows through the Schottky area, and hence the area of the second p-type layers 30 does not serve as a current path. Therefore, there is a tendency that losses in the forward direction are large. On the other hand, in cases where the third p-type layers 40 and the fourth p-type layer 39 are formed by implanting p-type ions (aluminum ions or the like) with a high energy into the substrate in the vicinity of the surface of the second semiconductor layer 3 as shown in FIG. 18 or where the third p-type layers 40 and the fourth p-type layer 39 are selectively formed in portions apart from the gate electrode by implanting ions into the surface of the substrate in order to form the third p-type layers 40 and the fourth p-type layer 39, then subjecting them to epitaxial growth and embedding these layers, when a forward voltage is applied, a current flows through the entire Schottky electrode 7. Accordingly, there can be obtained an advantage that deterioration in an on-state voltage due to the formation of the p-type layers can be suppressed. The third p-type layers 40 and the fourth p-type layer 39 are formed by ion implantation of aluminium or the like, and their dose is 1×10¹³ to 5×10¹⁴ cm⁻³. Any other structure is the same as the first embodiment, thereby eliminating its explanation.

It is to be noted that the fourth p-type layer 39 only may be provided and the third p-type layers 40 may be eliminated in the fourth embodiment. With such a configuration, the electric-field concentration at the end portion of the gate electrode 7 can be alleviated to some extent.

### Fifth Embodiment

FIG. 19 shows a cross-sectional view of a unit device constituting a semiconductor device according to a fifth embodiment. A difference of this embodiment from the third embodiment lies in that the third p-type layers 40 only are provided at a portion apart from the Schottky barrier even though this portion is directly below the Schottky barrier. Even if such a configuration is adopted, when a forward voltage is applied, since a current flows through the substantially entire Schottky electrode 7, there can be obtained an advantage that a deterioration in an on-state voltage due to the formation of the p-type layers can be suppressed. Any other structure is the same as the fourth embodiment, thereby eliminating its explanation.

According to the foregoing embodiments, it is possible to provide an SiC cascode device which does not require an external anti-parallel-connected diode but has a built-in high-speed anti-parallel diode. Incidentally, as the SiMOSFET 60 used in the SiC cascode device shown in FIG. 4, it is sufficient to use an SiMOSFET which is obtained by forming the source electrode, the drain electrode and the gate electrode on the silicon substrate separately from the SiCJFET 50 by a known method.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a semiconductor substrate including a first-conductivity-type impurity;
a first semiconductor layer formed on the semiconductor substrate including a first-conductivity-type impurity;
a second semiconductor layer formed on the first semiconductor layer and having a first-conductivity-type impurity concentration higher than that of the first semiconductor layer;
a first semiconductor region including a second-conductivity-type impurity, and selectively formed on an upper surface of the first semiconductor layer;
a source electrode selectively formed on the second semiconductor layer and achieves ohmic contact with the second semiconductor layer and the first semiconductor region;
a gate electrode selectively formed on the second semiconductor layer and achieves Schottky contact with the second semiconductor layer; and
a drain electrode formed on a lower surface of the semiconductor substrate and achieves ohmic contact with the semiconductor substrate.

2. The semiconductor device according to claim 1, wherein a height of a Schottky barrier which is comprised of the second semiconductor layer and the gate electrode is less than 1.1 eV.

3. The semiconductor device according to claim 1, further comprising a second semiconductor region which includes a second-conductivity-type impurity, and is selectively formed on an upper surface of the second semiconductor layer at a peripheral portion of the gate electrode, and at least a part of which is brought into contact with the gate electrode.

4. The semiconductor device according to claim 3, further comprising a third semiconductor region including a second-conductivity-type impurity and formed on the upper surface of the second semiconductor layer directly below the gate electrode so that the third semiconductor region comes into contact with the gate electrode.

5. The semiconductor device according to claim 3, further comprising a fourth semiconductor region including a second-conductivity-type impurity, and formed inside the second semiconductor layer directly below the gate electrode so that the fourth semiconductor region is apart from the gate electrode.

6. The semiconductor device according to claim 1, further comprising a fifth semiconductor region including a second-conductivity-type impurity, and formed inside the second semiconductor layer around a peripheral portion of the gate electrode so that the fifth semiconductor area is apart from the gate electrode.

7. The semiconductor device according to claim 6, further comprising a sixth semiconductor region including a second-conductivity-type impurity, and formed in the second semiconductor layer directly below the gate electrode so that the sixth semiconductor region is apart from the gate electrode.

8. The semiconductor device according to claim 1, wherein the semiconductor substrate, the first semiconductor layer, the second semiconductor layer and the first semiconductor region are formed of silicon carbide.

9. A semiconductor device comprising:
a junction field-effect transistor which has a first source electrode, a first drain electrode and a first gate electrode formed on a first semiconductor substrate, the first gate electrode achieving Schottky contact with the semiconductor substrate; and
a MIS field-effect transistor which has a second source electrode, a second drain electrode and a second gate electrode formed on a second semiconductor substrate, the second drain electrode being connected with the first source electrode.

10. The semiconductor device according to claim 9,
wherein the junction field-effect transistor comprises:
the first semiconductor substrate including a first conductivity type impurity;
a first semiconductor layer including a first-conductivity-type impurity, and formed on the first semiconductor substrate;
a second semiconductor layer formed on the first semiconductor layer and having a first-conductivity-type impurity concentration higher than that of the first semiconductor layer;
a first semiconductor region including a second-conductivity-type impurity, and selectively formed on an upper surface of the first semiconductor layer;
the first source electrode selectively formed on the second semiconductor layer and achieves ohmic contact with the second semiconductor layer and the first semiconductor region;
the first gate electrode selectively formed on the second semiconductor layer and achieves Schottky contact with the second semiconductor layer; and
the first drain electrode formed on a lower surface of the first semiconductor substrate and achieves ohmic contact with the first semiconductor substrate.

11. The semiconductor device according to claim 10, wherein a height of a Schottky barrier which is comprised of the second semiconductor layer and the first gate electrode is less than 1.1 eV.

12. The semiconductor device according to claim 10, further comprising a second semiconductor region including a second-conductivity-type impurity, and selectively formed on an upper surface of the second semiconductor layer at a peripheral portion of the first gate electrode, and at least a part of which is brought into contact with the first gate electrode.

13. The semiconductor device according to claim 12, further comprising a third semiconductor region including a second-conductivity-type impurity, and selectively formed on the upper surface of the second semiconductor layer directly below the first gate electrode so that the third semiconductor region comes into contact with the first gate electrode.

14. The semiconductor device according to claim 12, further comprising a fourth semiconductor region including a second-conductivity-type impurity, and formed inside the second semiconductor layer directly below the first gate electrode so that the fourth semiconductor region is apart from the first gate electrode.

15. The semiconductor device according to claim 10, further comprising a fifth semiconductor region including a second-conductivity-type impurity, and formed inside the second semiconductor layer around a peripheral portion of the first gate electrode so that the fifth semiconductor region is apart from the first gate electrode.

16. The semiconductor device according to claim 15, further comprising a sixth semiconductor region including a second-conductivity-type impurity, and formed in the second semiconductor layer directly below the first gate electrode so that the sixth semiconductor region is apart from the first gate electrode.

17. The semiconductor device according to claim 9, wherein the first semiconductor substrate is formed of silicon carbide.

18. A semiconductor device comprising:
a semiconductor substrate including a first-conductivity-type impurity;
a first semiconductor layer including a first-conductivity-type impurity, and formed on the semiconductor substrate;
a second semiconductor layer formed on the first semiconductor layer and having a first-conductivity-type impurity concentration higher than that of the first semiconductor layer;
a first semiconductor region including a second-conductivity-type impurity, and selectively formed on an upper surface of the first semiconductor layer;
a source electrode selectively formed on the second semiconductor layer and achieves ohmic contact with the second semiconductor layer and the first semiconductor region;
a gate electrode selectively formed on the second semiconductor layer and achieves Schottky contact with the second semiconductor layer;
a plurality of second semiconductor regions each including a second-conductivity-type impurity, and selectively formed on the second semiconductor layer below the gate electrode; and
a drain electrode formed on a lower surface of the semiconductor substrate and achieves ohmic contact with the semiconductor substrate.

19. The semiconductor device according to claim 18, wherein a height of a Schottky barrier which is comprised of the second semiconductor layer and the gate electrode is smaller than 1.1 eV.

20. The semiconductor device according to claim 18, wherein the semiconductor substrate, the first semiconductor layer, the second semiconductor layer, the first semiconductor region and the second semiconductor region are formed of silicon carbide.
